(19) United States
(12) Patent Application Publication
(10) Pub. No.: US 2017/0113928 A1
(43) Pub. Date: Apr. 27, 2017

(54) DEVICE AND METHOD FOR PRODUCING A DEVICE COMPRISING MICRO OR NANOSTRUCTURES

(71) Applicant: Fraunhofer-Gesellschaft zur Foerderung der angewandten Forschung e.V, Muenchen (DE)

(72) Inventors: Andreas GOEHLICH, Rheurdt (DE); Andreas JUPE, Dortmund (DE); Holger VOGT, Muehlheim (DE)

(21) Appl. No.: 15/400,665

(22) Filed: Jan. 6, 2017

Related U.S. Application Data
(63) Continuation of application No. PCT/EP2015/065629, filed on Jul. 8, 2015.

(30) Foreign Application Priority Data
Jul. 9, 2014 (DE) 102014213390.4

(51) Int. Cl. B81C 1/00; B81B 7/00

(52) U.S. Cl. CPC B81C 1/00619; B81B 7/0003; B81B 2201/0207; B81B 2201/0214; B81B 2201/042; B81C 2201/0187

(57) ABSTRACT

What is described is a method for producing a device having providing a substrate having an electrode which is exposed at a main side of the substrate. In addition, the method has forming a micro or nanostructure which has a spacer which is based on the electrode, wherein forming has the steps of: depositing a sacrificial layer on the main side, wherein the sacrificial layer has amorphous silicon or silicon dioxide; patterning a hole and/or trench into the sacrificial layer by means of a DRIE process; coating the sacrificial layer by means of ALD or MOCVD so that material of the nano or microstructure forms at the hole and/or trench, and removing the sacrificial layer.

### CROSS-REFERENCE TO RELATED APPLICATIONS

This application is a continuation of copending International Application No. PCT/EP2015/065629, filed Jul. 8, 2015, which claims priority from German Application No. 102014213390.4, filed Jul. 9, 2014, which are each incorporated herein in its entirety by this reference thereto.

### BACKGROUND OF THE INVENTION

The present invention relates to a device comprising at least one electrode and a micro or nanostructure which is based thereon, and to a production method for producing such a device. The device is, for example, integrated on a CMOS semiconductor substrate.

So-called template methods are known for producing 3D-ALD nanostructures. ALD means atomic layer deposition. This is a method for depositing thin conformal layers.

An example thereof is described in the publication “Ru nanostructure fabrication using an anodic aluminum oxide nanotemplate and highly conformal Ru atomic layer deposition” by Woo-Hee Kim, Sang-Joon Park, Jong-Yeog Son and Hyungjun Kim in Nanotechnology 19 (2008) 045302 (8 pp). An anodically oxidized self-organized aluminum template is used here for molding Ru nanowires. The production methods used, however, are not available in CMOS clean rooms.

Producing supported ALD nanostructures is known already from Ra and others [H. W. Ra, Kwang-Sung Choi, J-H. Kim, Y-B Hahn, Y. H. IM: “Fabrication of ZnO Nanowires Using Nanoscale Spacer Lithography for Gas Sensors”, Small 2008, 4, No. 8, 1105-1109] and from S. M. Sultan [Suhana Mohamed Sultan and others: “Electrical Characteristics of Top-Down ZnO Nanowire Transistors Using Remote Plasma”, IEEE Electron Device Letters, VOL. 33, No. 2, February 2012]. In these citations, the so-called spacer technology is used for producing ALD nanowires. ALD layers are deposited on patterned oxide sacrificial layers and etched back anisotropically so that “sidewall spacers” remain along the patterns. These methods are compatible with CMOS, but do not provide self-supporting nanostructures.

US 2011/0250706 A1 shows a method for producing MEMS and NEMS structures by means of different process modules such as, for example, surface micromachining on a (semiconductor) substrate. Self-supporting polysilicon structures are, for example, produced here on a sacrificial layer made of oxide. However, due to the high process temperatures used when depositing layers from which the surface structures are formed, this method cannot be integrated into CMOS technology, since existing CMOS circuits or members in the substrate may be damaged or destroyed. As an alternative solution approach, US 2011/0250706 A1 shows processing the substrate by means of bulk micromachining. Structures of great an aspect ratio may, for example, be etched into the substrate by means of DRIE (deep reactive ion etch). However, valuable space of the substrate is consumed here by etching into the substrate, which otherwise could be used for semiconductor structures or circuits.

Consequently, improving the micro and nanostructures and the production methods thereof would be desirable.

The object underlying the present invention is providing a device comprising a micro or nanostructure and a production method for same which are more effective as regards producibility and/or compactness, for example, and may, for example be produced using conventional semiconductor technology methods.

### SUMMARY

According to an embodiment, a method for producing a device may have the steps of: providing a substrate having an electrode which is exposed at a main side of the substrate, and forming a micro or nanostructure which has a spacer which is based on the electrode, wherein forming has the steps of: depositing a sacrificial layer on the main side, wherein the sacrificial layer has amorphous silicon; patterning a hole and/or trench into the sacrificial layer by means of a DRIE process; coating the sacrificial layer by means of ALD so that material of the nano or microstructure forms at the hole and/or trench; removing the sacrificial layer.

According to another embodiment, a device may have a substrate which has an electrode which is exposed at a main side of the substrate, a micro or nanostructure which has a spacer which is based on the electrode, wherein the micro or nanostructure is produced by means of ALD coating a sacrificial layer patterned by the DRIE process, on the main side of the substrate and subsequently removing the sacrificial layer, wherein the sacrificial layer has amorphous silicon.

The present invention is based on the idea that micro or nanostructures can be generated by DRIE (deep reactive ion etch) etching into a sacrificial layer and subsequently coating using an ALD or MOCVD method. Depending on the type of patterning or etching into the sacrificial layer, after removing same, spacers, like thin free-standing areas or U-profiles or free-standing, filled or solid or hollow pins, remain, for example.

In accordance with an embodiment, sacrificial layer deposition, DRIE patterning and coating using ALD or MOCVD are repeated several times in order to form a self-supporting micro or nanostructure, for example, so that a self-supporting structure of the micro or nanostructure, after removing the sacrificial layer and after repeating etching and coating several times, is suspended at one or several spacers to be self-supporting. A sensor, like a gas sensor, may be produced, for example. Structures stacked one above the other may also be produced so that the micro or nanostructures are arranged in three dimensions. Thus, a considerably greater surface area can be formed, which may be of advantage in sensors which are based on surface reactions, for example.

In addition, the method is CMOS-compatible and, thus, allows integration into existing CMOS manufacturing steps. CMOS compatibility is, among others, based on the fact that the materials used do not impair the CMOS manufacturing steps by contamination. In addition, particularly a-Si may be patterned by means of the DRIE process (so-called “Bosch” process) in a highly selective manner relative to passivating the substrate and the electrode and be removed isotropically in a selective manner using SF₆ or XeF₂, without damaging other elements of the device. Furthermore, all the steps necessitated may be performed at (comparably) low temperatures, thereby not influencing, damaging or destroying CMOS circuits. Thus, sacrificial layers comprising a-Si or SiO₂, and ALD layers, for example, may be deposited at temperatures which do not influence underlying circuits in the substrate, like CMOS circuits. In addition, sacrificial layers comprising a-Si may, for example, be removed by means of SF₆ (sulphur hexafluoride) or XeF₂ (xenon difluoride) and sacrificial layers comprising SiO₂ may be removed using HF vapor. All the methods mentioned for removing the sacrificial layers are CMOS-compatible or generally compatible with semiconductor production, that is do not attack the substrate and do not use high temperatures for removing the sacrificial layers, nor do high temperatures result when removing the sacrificial layers, which, for example, damage or destroy CMOS circuits, CMOS structures or, generally, semiconductor structures.

### BRIEF DESCRIPTION OF THE DRAWINGS

Embodiments of the present application will be detailed subsequently referring to the appended drawings, in which:

FIG. 1a is a schematic illustration of a device comprising an integrated member and a substrate and a spacer contacted at the substrate,

FIG. 1b is a schematic illustration of a cross-section of a device comprising an integrated member and spacers contacting the member,

FIG. 2a-2f are schematic illustrations of the method steps for producing spacers,

FIGS. 3a, b are schematic illustrations of round, tubular spacers arranged in a group,

FIG. 3c is a schematic illustration of planar spacers,

FIG. 4 shows a flow chart of method steps for producing self-supporting elements on the spacers,

FIG. 5a-5f are step-by-step illustrations for producing the self-supporting elements in cross-section,

FIGS. 6a, b are schematic illustrations of a self-supporting element including two different materials in cross-section,

FIGS. 7a, b are schematic illustrations of a resistive bridge as an example of a sensor arranged on interdigital electrodes,

FIG. 8 is a schematic illustration of a spacer comprising a self-supporting element which is arranged on another self-supporting element and which may, thus, form a stacked sensor,

FIG. 9 is a schematic illustration of a self-supporting element suspended only at one spacer,

FIG. 10 shows a flow chart of the method steps for forming nanowires and spacers,

FIG. 11 is a schematic Illustration of nanowires between spacers,

FIG. 12a shows a representation of the process cross-sections,

FIGS. 12b-d show schematic layouts for illustrating different process cross-sections for producing nanowires,

FIGS. 13a, b show schematic illustrations of a membrane sensor,

FIG. 13c is a schematic illustration of a self-supporting membrane employed as a tunable optical element on a CMOS substrate,

FIG. 13d shows a section of FIG. 13c with a deflected membrane 90,

FIG. 14 is a schematic illustration of a hermetically sealed housing hermetically shielding the elements integrated in the substrate and the spacers and the self-supporting element from the outside,

FIG. 15 is a schematic illustration of a device comprising two spacers, wherein the spacers are mechanically reinforced on the substrate by an additional layer, and

FIG. 16 is a basic illustration of a cross-section of a hole etched using a Bosch process.

### DETAILED DESCRIPTION OF THE INVENTION

In the following description of the Figures, equal elements or elements of equal effect are provided with equal reference numerals so that the description thereof in the different embodiments is mutually exchangeable.

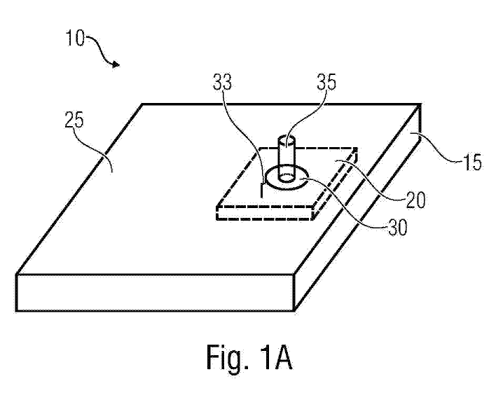

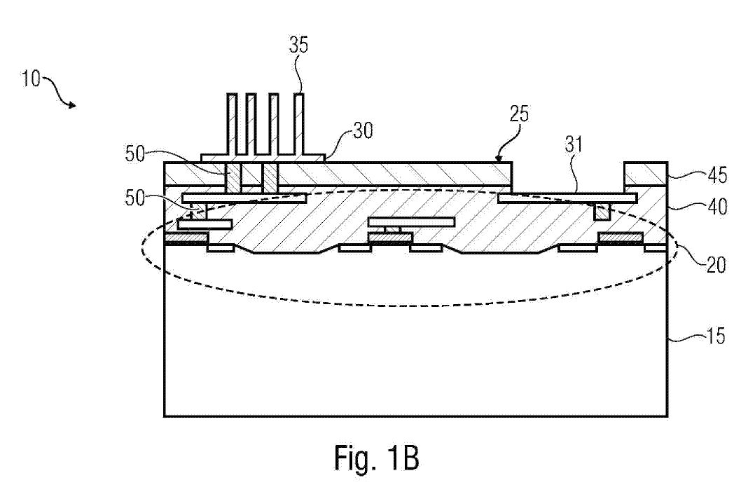

FIG. 1a shows a device 10 which comprises a wafer substrate 15 and, optionally, a member 20 integrated therein. Additionally, on a main side 25 of the wafer substrate, an electrode 30 is exposed, which in case the integrated member 20, for example a member of a CMOS circuit, like a transistor, is formed, electrically contacts same by means of a connective element 33. A micro or nanostructure which comprises a spacer 35 is arranged on the electrode. The spacer 35 may be produced in a sacrificial layer process, for example by etching an opening into a sacrificial layer, in particular a-Si, for example by means of a DRIE process, like a Bosch or cryo-process, which is then coated using a super-conformally depositing coating method, like the ALD method. An “ALD layer” is a “superconformally” depositing layer which can be deposited atomic layer by atomic layer. Another advantage of the ALD technology may be that a plurality of materials may be realized by selecting corresponding chemical precursors. Super-conformity also applies to so-called MOCVD (metal organic chemical vapor deposition) layers. It will be described below how this production method may be of advantage, for example when forming sensors.

FIG. 1b shows a schematic illustration of a cross-section of the device 10 comprising an integrated member 20 and spacers 35 contacting the member. The device 10 may, for example, comprise a wafer substrate 15 and members 20 integrated therein, or consist of same. The integrated members 20 may be connected via at least one metal sheet 40 and vias 50 to form an electrical circuit, for example read-out and control circuit. A passivation layer 45 may be applied on the at least one metal sheet, on which additionally an electrode 30 electrically contacts the spacers 35. The electrode 30 may be connected electrically to the at least one metal sheet 40 via vias 50 through the passivation layer 45. Additionally, a terminal pad 31, for example made of aluminum, may be present on the main side 25 of the device 10 or, alternatively, the passivation may be opened over the terminal pad of the wafer substrate.

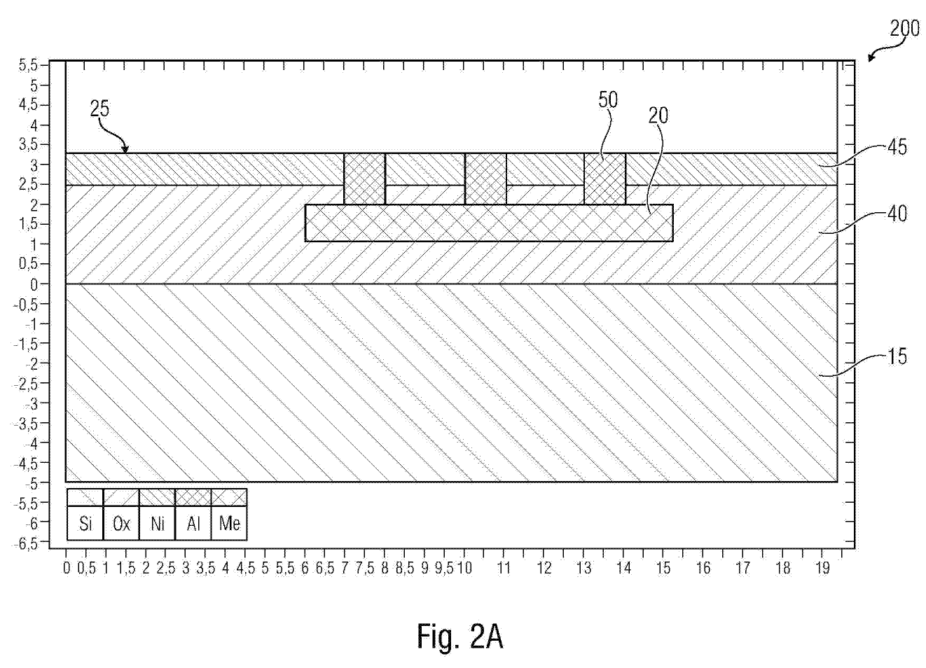

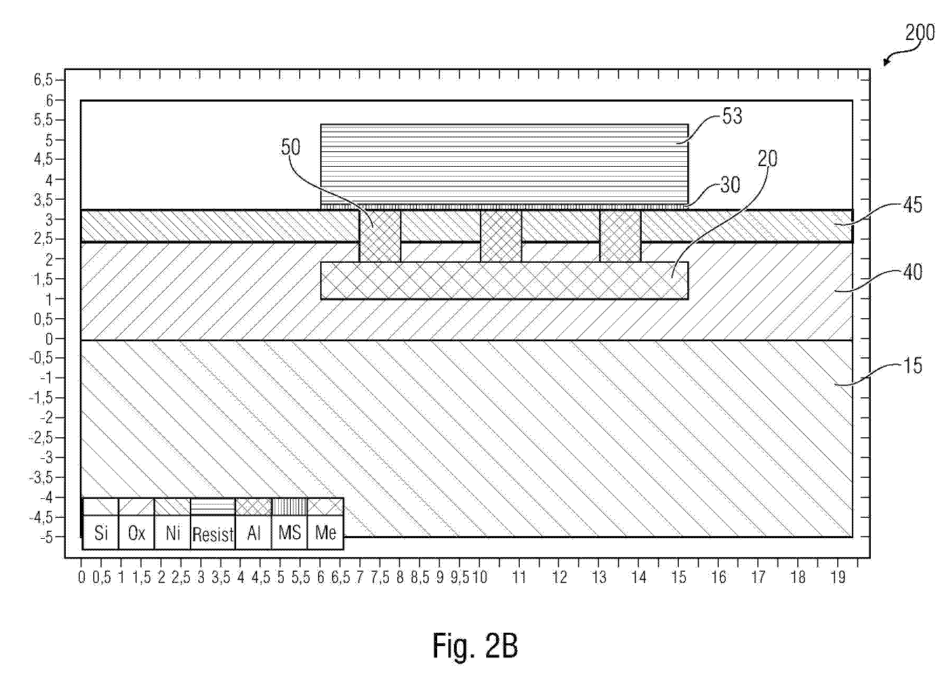

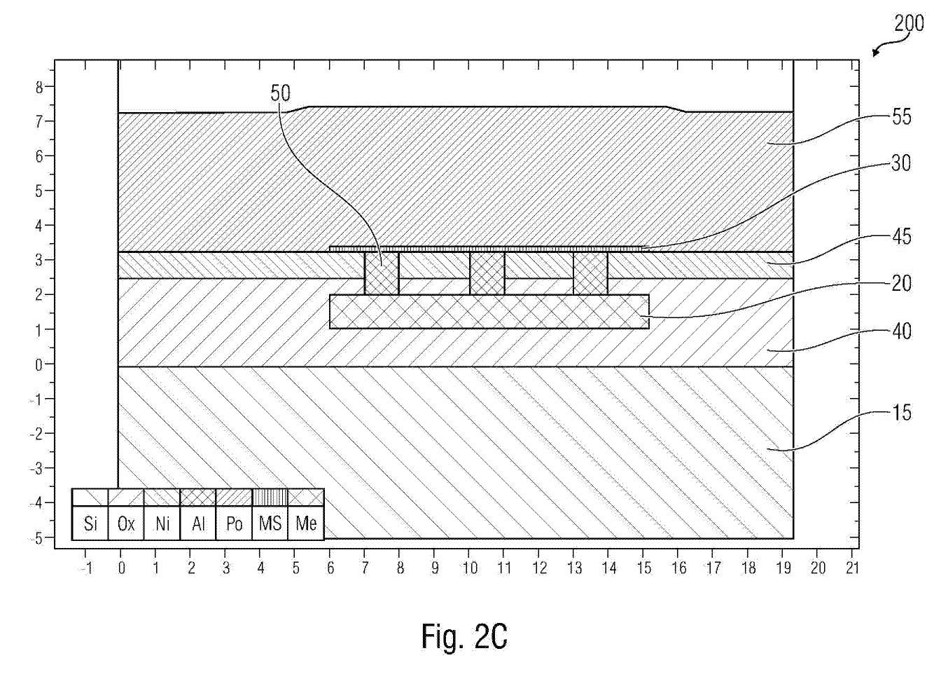

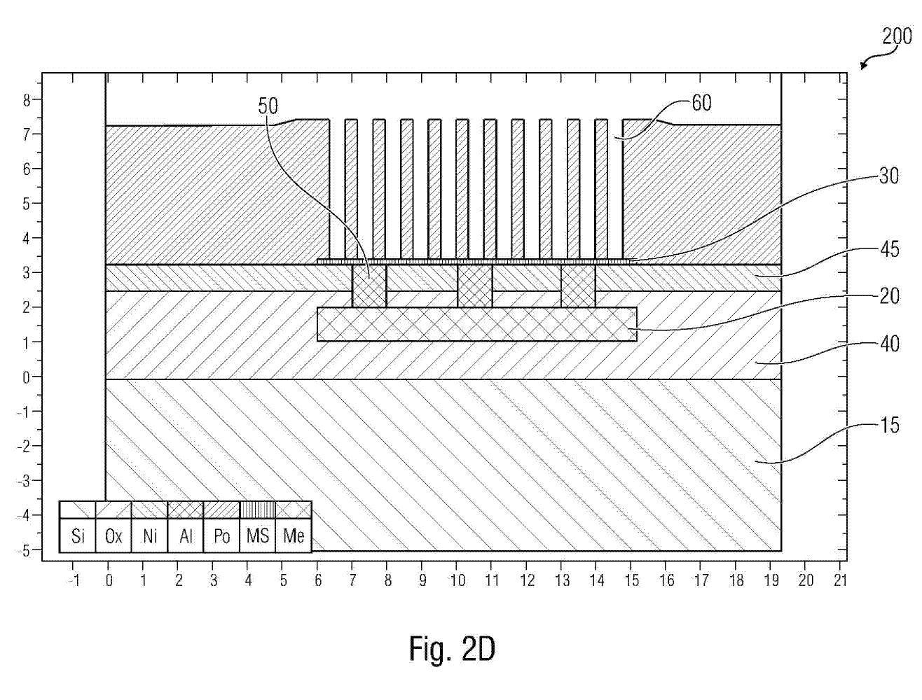

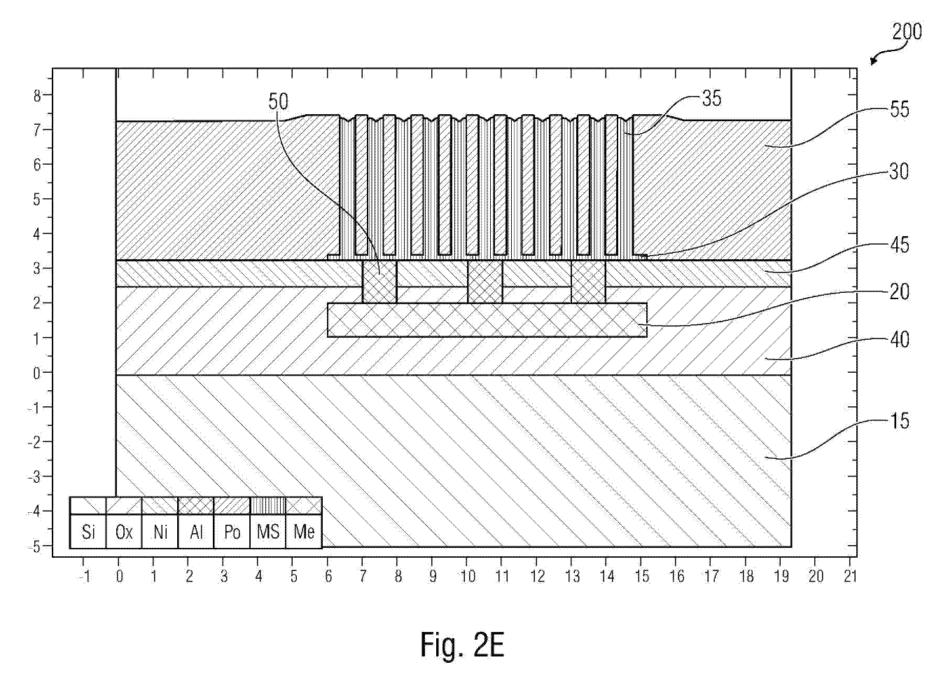

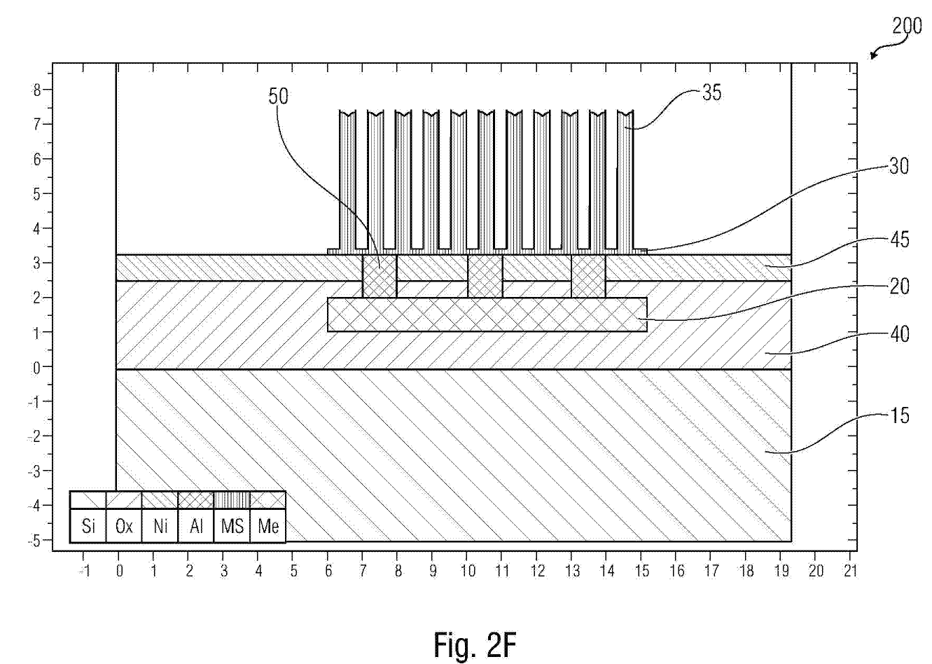

The inventive basic process 200 is illustrated using a device illustrated following the process steps in FIGS. 2a-f and is described here as an example of producing 3D nanotubes, for example for a realization as a multi-electrode array in medical technology. The process flow including additional masks will be described subsequently.

FIG. 2a shows the device in the process 200, which is based on a wafer substrate 15, for example a CMOS substrate, having a planarized surface, for example. The device is illustrated so as to comprise a metal sheet 40, for example made of aluminum, and a passivation layer 45, for example made of SiN and/or an oxide. However, depending on the complexity of the integrated member 20, for example with substrates comprising a CMOS circuit, there may be several metal sheets. Vias 50, for example so-called wolfram plugs, which may form the connective element 33, may be formed in the surface of the passivation. The vias 50 are able to electrically connect electrically conductive structures to the integrated member 20, for example a read-out or control circuit or electrical line, in the wafer substrate. The read-out and control circuit may, for example, be formed for data processing or driving. The electrical line may additionally be configured to electrically contact a terminal pad, for example, or perform potential compensation between the vias 50. Terminal pads, for example made of aluminum, may be present on the surface of the wafer substrate, or, alternatively, the passivation may be opened over the terminal pads of the wafer substrate.

FIG. 2b shows the device after producing “basic electrodes” 30 on the passivation layer 45. An electrode layer made of a conductive layer, for example Ti and TiN, may be applied, advantageously sputtered for producing the basic electrodes. An aluminum layer, for example, is also possible here. The typical layer thickness for the basic electrode may be approximately 20 to 200 nm. The basic electrode may be patterned through a first lithography plane, for example using a mask, to form circular electrodes, for example.

FIG. 2c shows the device after applying a sacrificial layer 55, for example made of amorphous silicon (a-Si), comprising a thickness of, for example, some micrometers, onto the basic electrodes. When the sacrificial layer is formed from amorphous silicon, the so-called Bosch process may advantageously be employed as the DRIE process. Further materials, for example silicon dioxide (SiO₂), are also conceivable for the sacrificial layer, which may be removed selectively relative to the substrate, for example using other etching methods. In addition, the sacrificial layer is to allow a great aspect ratio, i.e. the ratio of a height perpendicular to the main side of the substrate relative to a width parallel to the main side of the substrate, for holes or trenches introduced into the sacrificial layer, and be compatible with the substrate, i.e. same or even processing steps thereof are not to attack or damage the substrate.

FIG. 2d shows the device after introducing holes or narrow trenches 60 into the sacrificial layer at high an aspect ratio (for example 1:10 to 1:20). For introducing the holes or trenches, a DRIE (deep reactive ion etch) process for etching the sacrificial material, for example a so-called Bosch process of small a surface roughness (“low scalloping”) may be used. The Bosch process basically is a sequence of polymerizing sidewall passivation steps using C₄F₈, an anisotropic opening step for removing the passivation at the floor (typically achieved by increasing the ion energy) of the etched structure, and an isotropic silicon etching step using SF₆. A so-called cryo-process, which allows realizing very smooth surfaces is an alternative to the Bosch process mentioned. The DRIE process is dimensioned such that etching stops on the basic electrode 30 as selectively as possible.

FIG. 2e shows the device after filling the etched structures by a conformally depositing layer 65, for example produced by a so-called ALD (atomic layer deposition). Ruthenium ALD layers, which are comparably easy to produce at a comparably high deposition rate using ALD technology are, for example, suitable for producing metallic electrodes. These layers are of advantage in that they may exhibit good quality (for example no/little “pinholes”), good mechanical stability and high electrical conductivity. In particular, very thin layers (1-100 nm) may be realized precisely by the deposition time of the ALD process. The layer thickness may be selected such that the etched holes are closed completely—in this case filled, needle-like structures will form, or such that only the walls of the etched holes are covered, wherein in this case tubular structures will result. When etching trenches instead of holes, the result will be thin, parallel walls at the lateral trench confinements, which may be connected at the floor and form a U profile, or alternatively a filled “wall” over the width of the trench. In the field of electrode arrays for nerve stimulation, ruthenium may be employed advantageously, which is bio-compatible and, thus, is well-suited for electrode structures in medical technology. After depositing the ALD layer, same may be removed again over the entire area, for example using ion beam etching, unmasked at the surface. Alternatively, another photo technology may be used for patterning the ALD layer on the a-Si surface, as is shown in further embodiments.

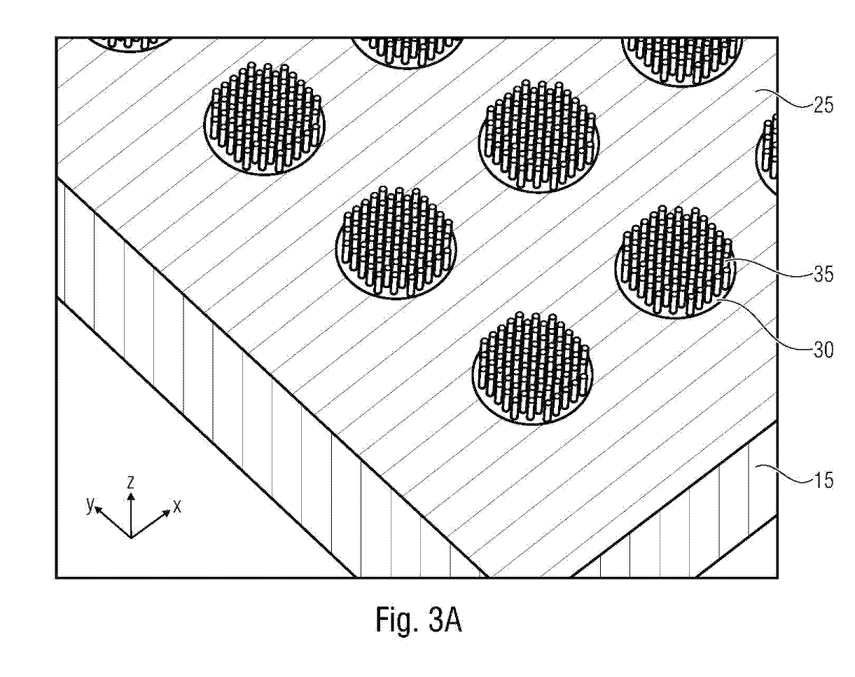

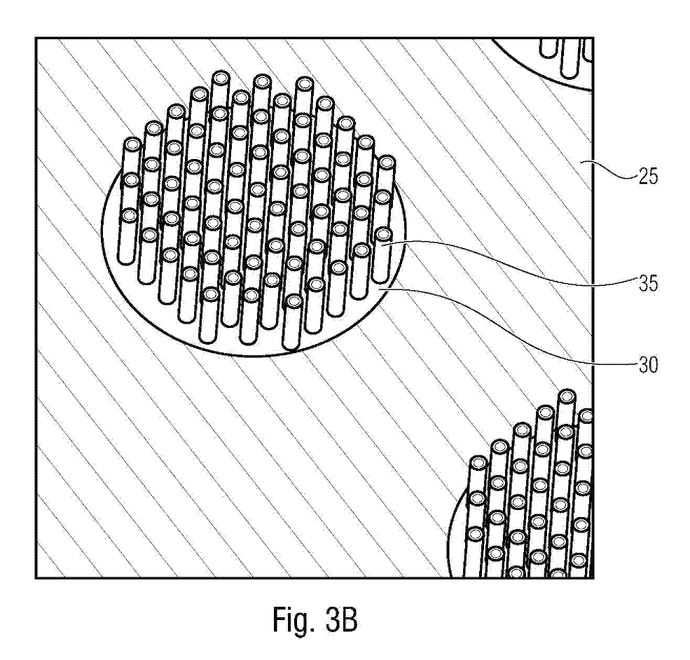

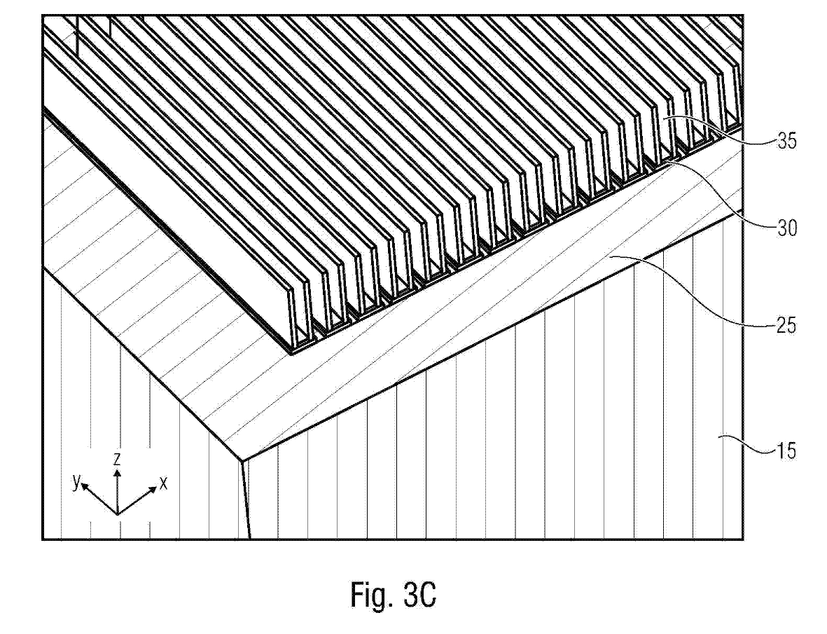

FIG. 2f shows the device after removing the sacrificial layer. The sacrificial layer, for example made of a-Si, may be removed using an isotropic etching step using XeF₂ or SF₆. When SiO₂ has been used for the sacrificial layer, HF vapor may, for example be used for removing same. This etching step removes the sacrificial material highly selectively relative to the other materials so that spacers as 3D nanotubes remain, for example (when holes were etched in the DRIE step). When, however, trenches were etched in the DRIE step, self-supporting perpendicular walls which may, for example, be used as capacitive electrodes in sensor systems will result (see FIG. 3c, for example). It may be of advantage to perform wafer dicing, for example by sawing the wafer, before isotropically etching the a-Si layer in order to keep the mechanical influence of sawing on the 3D structures small. The resulting 3D structures may be connected electrically and be provided with an electrical voltage or current.

An advantage of the inventive process flow or the sensors and actuators formed thereby is that the process steps may be performed by “conventional” apparatuses of semiconductor manufacturing, after producing the CMOS substrate by CMOS-compatible steps (post-CMOS technology). This allows producing cheap CMOS-integrated sensors or actuators.

FIGS. 3a-c show embodiments of the method described above. FIG. 3a shows spacers 35 arranged in groups on an electrode 30. The surface area of every basic electrode may be increased by this. By varying the layout, it is, for example, possible for individual spacers 35, exemplarily implemented as nan needles, to be contacted so that electrode arrays of a high spatial resolution are possible. The minimum distance between the individual nanoneedles 35 is, thus, basically limited by the design rules (in particular distance between the vias 50) of the underlying CMOS process. The nanoneedles or spacers may be formed to be hollow inside and/or solid, i.e. the depositing process of an ALD layer is, for example, stopped when a preset layer thickness has been obtained, for example for forming hollow needles, or the depositing process is performed until the etched hole (or the etched trench) in the sacrificial layer has been filled completely. Every spacer may principally be connected individually or in small groups so that imaging electrode arrays are possible, which allow space-resolving information or stimulation. In other words, a spacer may be arranged regularly in the form of a matrix, together with further spacers which are arranged on the main side and based on further electrodes. Additionally or alternatively, a plurality of spacers may also be arranged on a (single) electrode. FIG. 3b shows an enlarged section of FIG. 3a.

FIG. 3c shows an alternative implementation of free-standing capacitive structures. Instead of needles or tubes, the spacers may, for example, also be implemented as walls or plates or U profiles. This structure may be used to measure changes in the dielectric constant, for example in impedance-spectroscopic sensors. Not only parallel planar electrodes may be realized by this method, but planar 3D electrode structures of any shape. Electron or ion-optical CMOS-integrated elements may be realized, for example.

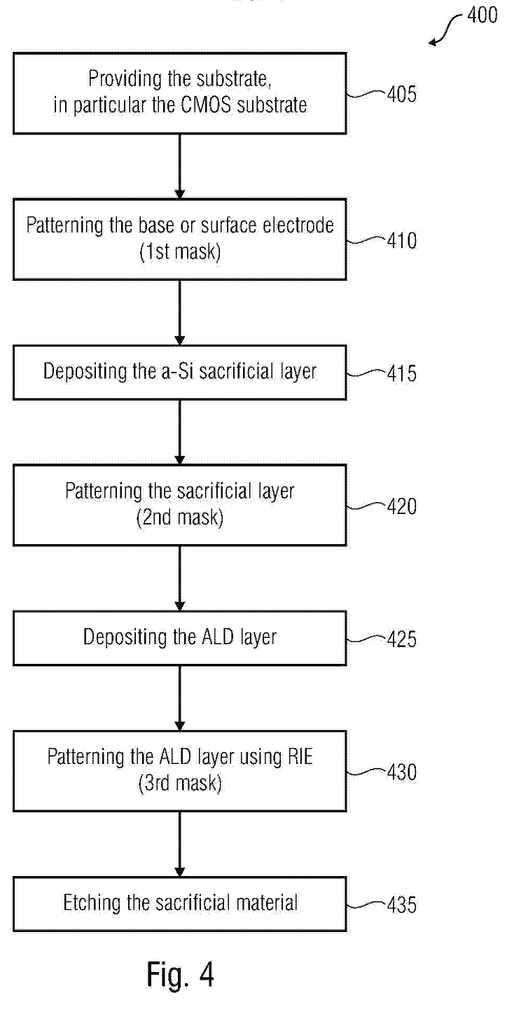

FIG. 4 shows another inventive process 400. Based on the spacers described before, the process forms self-supporting micro or nanostructures. The spacers discussed already are produced up to depositing the ALD layer, i.e. steps 405-425 describe the process steps described already in FIGS. 2a-e. A thin ALD layer is still placed on the sacrificial material. Instead of removing the ALD layer by a selective surface etch process, for example, it is patterned for example by a lithographic process, for example by means of an RIE (reactive ion etching) process to form the desired shape of a self-supporting element, i.e. removed only partly. This may, for example, take place using another mask. The self-supporting element may, for example, form a connection between two or several spacers (bridge) or be connected only to spacers arranged at one side, for example for forming a cantilever. After etching the sacrificial material, the self-supporting element is suspended to be self-supporting at the one or several spacers.

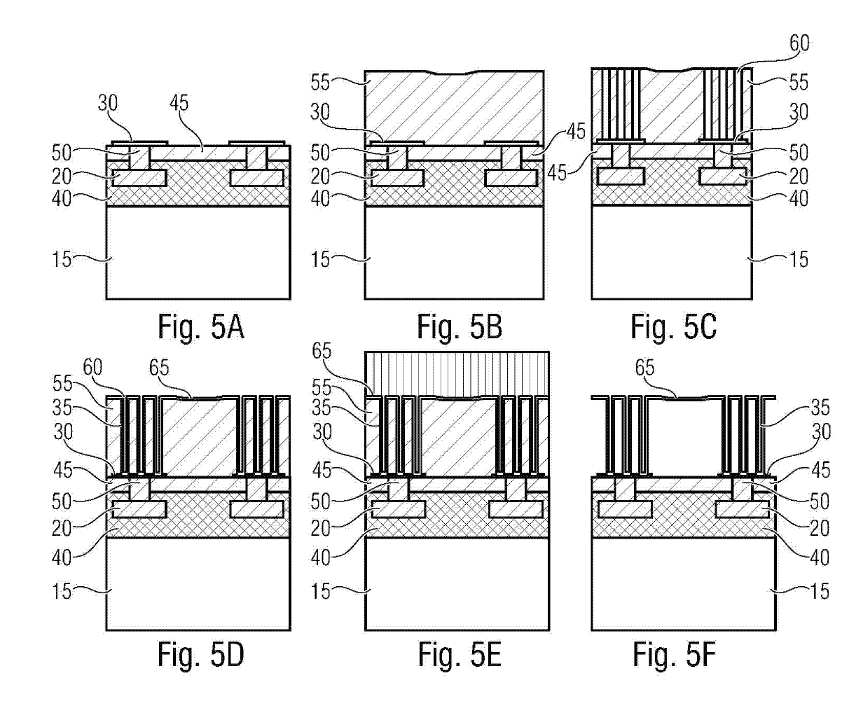

FIGS. 5a-f show a schematic illustration, in cross-section, of the device after the process steps of the process 400 of producing self-supporting structures 65 using another, additional mask. The Figures are illustrated in analogy to the steps in the flow chart of FIG. 4, wherein providing the substrate 15 and patterning the basic or surface electrode 30 (steps 405 and 410) are summarized in FIG. 5a. The steps in FIGS. 5a-d additionally correspond to FIGS. 2a-e and have already been described in detail. The process flow includes the following steps in accordance with FIG. 4:
405: providing the substrate, in particular the CMOS substrate
410: patterning the basic electrodes (1^{st} mask) (FIG. 5a)
415: depositing the a-Si sacrificial layer (FIG. 5b)
420: patterning the sacrificial layer (2^{nd} mask) (FIG. 5c)
425: depositing the ALD layer (FIG. 5d)
430: patterning the ALD layer using RIE (3^{rd} mask) (FIG. 5e)
435: etching the sacrificial material (FIG. 5f)

FIG. 5e shows the device after depositing the ALD layer, which has been patterned, for example, using an additional mask on the a-Si, i.e. the sacrificial layer 55. This provides electrical and mechanical connections between the coated or filled holes and the coated or filled trenches. The layout here may be implemented such that the masked area on the ALD layer may cover holes or trenches. Self-supporting structures 65 electrically connected on both sides may, thus, be formed from the ALD material. Examples here are self-supporting bridges made of the ALD material. When spanning the bridges between the contacts, a micro or nanofuse may, for example, be realized. In this way, information may, for example, be stored in a binary manner by the two states of the fuse (conductive or non-conductive). A metallic conductive material, like ruthenium, may, for example, be used as the ALD material.

FIG. 5f shows the device after removing the sacrificial layer.

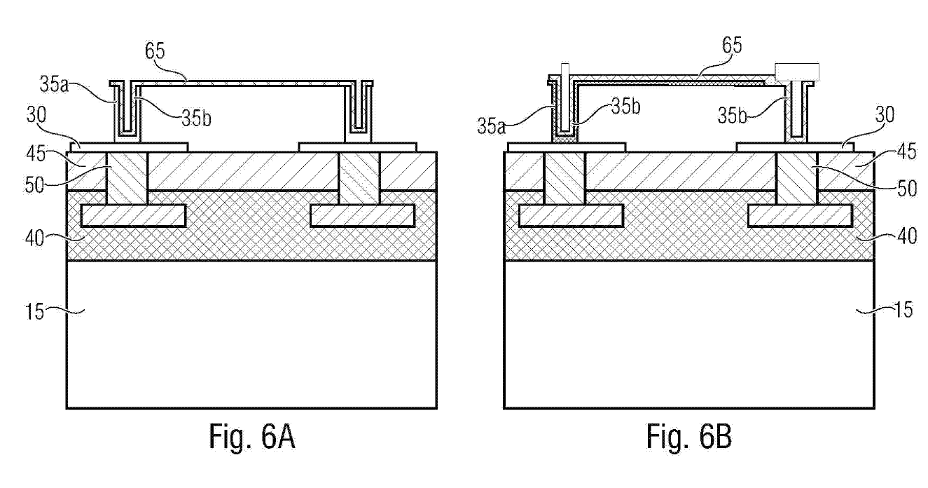

FIG. 6a shows another embodiment. It may be favorable to form post-like structures 35 from a different ALD material than the bridge-like structures 65, as is shown in FIG. 6a. The tubes 35 may, for example, be formed as a metallic terminal from a conductive ALD material, for example RU, and the bridge 65 be formed from a sensor material, for example ZnO or SnO₂. The first material 35a (for example ruthenium) here may be etched back over the entire area before step 430 in FIG. 4 or the step in FIG. 5e so that the layer remains in the holes and after that an ALD layer from another material (for example ZnO) may be applied. After that, there is a layer stack from both materials (for example metallic 35a and sensor 35b material) in the holes, wherein the sensor material is electrically shorted by the metallic material. The bridge, in contrast, includes only the sensor, in particular semi-conducting material. Thus, the electrical resistance of the posts may be reduced and the posts be reinforced mechanically. The advantage of a material combination is a way of producing novel, resistive sensor elements with semi-conducting materials, for example light- or IR-sensitive elements. In addition, so-called (micro) bolometers with a self-supporting ALD membrane may be produced.

FIG. 6b shows another embodiment comprising a self-supporting element 65 made from two different layers, a so-called nanobridge with two ALD layers. In other words, the self-supporting element may be formed from overlapping layers of different materials. Compared to the structure in accordance with FIG. 6a, two additional masks are necessitated here. After patterning the basic electrodes (using FT 1, FT=photo technique), at first the left hole can be etched (using FT2), ALD material 35a be deposited and patterned (FT 3). Subsequently, the right hole can be etched (FT4) and material 35b be deposited and patterned (FT 5). Subsequently, the sacrificial layer, for example the a-Si, is removed. This structure, or the overlapping layers of different materials, may be configured or be used to make use of the sensor characteristics of the interface of different materials (for example using a pn junction with differently doped materials or making use of the Seebeck effect for realizing thermal pairs/thermal columns or thermal piles). It is also possible to produce light-emitting structures by this, wherein the layer interface between the ALD layers forms an electroluminescence, for example.

An example of a sensor is a resistive bridge made of a sensorically acting material, for example for realizing gas sensors. In this case, an ALD layer made from ZnO or SnO₂ may, for example, be used sensorically. Expressed in other words, it is to be noted that adsorbing atoms or molecules change the conductivity of the semi-conducting (for example poly or nanocrystalline) semiconductor films. For implementing the poly or nanocrystallinity, it may also be necessitated to subject the ALD layers to suitable tempering treatments. The change in conductivity is based on the modulation of the space charge zone by charge exchange reactions with the adsorbed material. The ALD layers may be used advantageously. These may comprise a layer thickness in the order of magnitude of the space charge zone, thereby making modulation of the space charge zone easy. These nanobridges may advantageously be set up on finger electrodes in order to achieve a large sensitive area with a great surface-to-volume ratio.

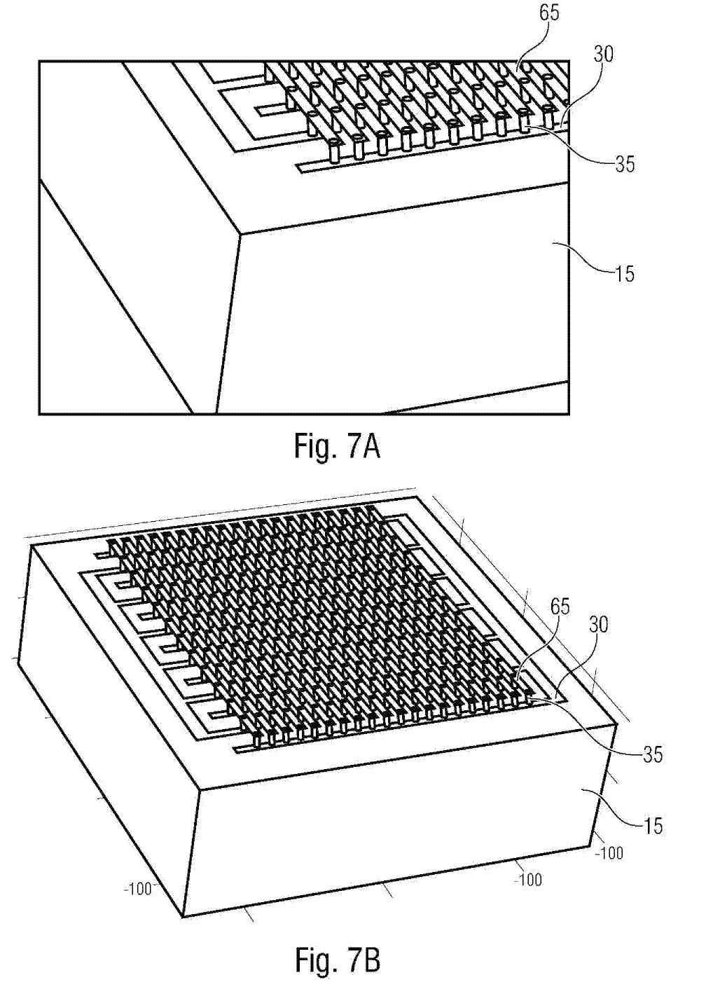

FIGS. 7a, b show a possible arrangement of the bridges. A plurality of self-supporting bridges 65 are connected in parallel by the arrangement, and the sensor area is, thus, spanned over an area for increasing the sensor area (for example for a gas sensor). A desired resistance may be realized by the number of bridges. In this example, each bridge is connected to the finger electrodes via two posts 35. However, it is also possible to connect the bridges individually, for example for achieving imaging systems. Each pixel, represented by a self-supporting element, may, however, be comparably small. The pixel size is basically determined by the design rules of the top metal sheet of the base technology. FIG. 7b shows an enlarged section of FIG. 7a.

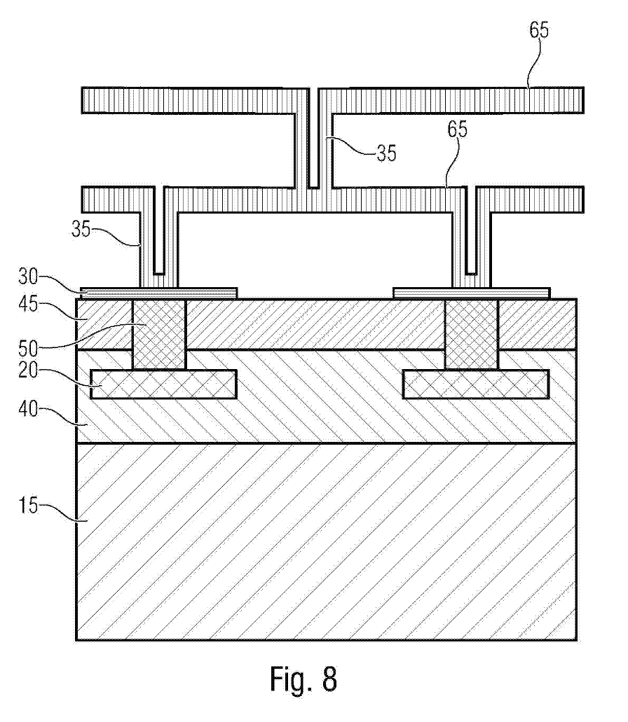

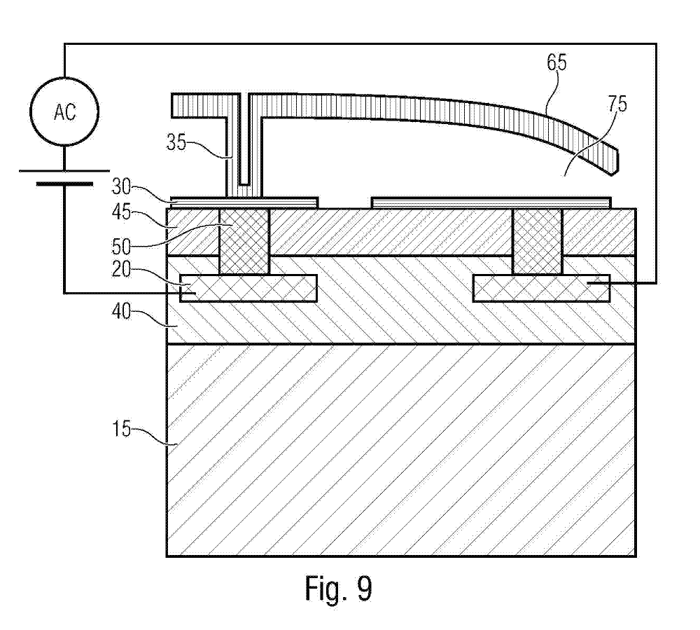

FIG. 8 shows an embodiment in which another spacer and another self-supporting element are arranged on the self-supporting element. This option of implementing the process in several layers is another advantage of the technology discussed. In an iterative process, the process steps of depositing the sacrificial layer, patterning the sacrificial layer, depositing the ALD layer, and patterning the ALD layer may be repeated as frequently as desired in order to produce a device made from several equal or differing layers or sheets. Patterning the sacrificial layer, for example etching trenches or holes in the sacrificial layer, can be performed such that it is limited to the current sacrificial layer, which means that sacrificial layers having been processed already in a previous iteration step are not influenced at all or only hardly influenced. Exemplarily, spacers and/or self-supporting elements, i.e. elements which are self-supporting after removing the sacrificial layer, may serve as a barrier for patterning, for example as an etch stop. Sacrificial etching of, for example, the amorphous silicon may be performed after stacking the planes of spacers and self-supporting elements so that the layers of the sacrificial layer applied one after the other can be removed together. Thus, nanobridges may be stacked one above the other in several planes in order to obtain a further increase of the surface area. 3D networks may be realized by this, which allow any desired arrangement of spacers and self-supporting elements.

In other words, the method for producing a device 10 comprising micro or nanostructures comprises a repetitive sequence of the following steps. Depositing a sacrificial layer on the main side, patterning a hole and/or trench in the sacrificial layer by means of a DRIE process, and coating the sacrificial layer by means of ALD or MOCVD so that material of the nano or microstructure forms at the walls of the hole and/or trench.

FIG. 9 illustrates an embodiment in which the self-supporting element 65, in contrast to the illustrations so far, is suspended at one instead of two spacers 35. This allows realizing beam-like structures, for example “cantilevers”, which may be excited electrostatically by generating an electrostatic field between the electrodes, for example. The beam of these structures may, for example, be excited to resonant mechanical vibrations by means of superimposing a direct and an alternating voltage. The resonant frequency decreases when applying additional mass on the vibrating beam structure. Advantageously, the movable beam may be provided with a selective “catching layer” for analytes. This allows realizing mass-sensitive sensors. In other words, the device 10 may form a resonant sensor as a self-supporting membrane structure comprising an underlying fixed supported electrode for electrostatic actuation.

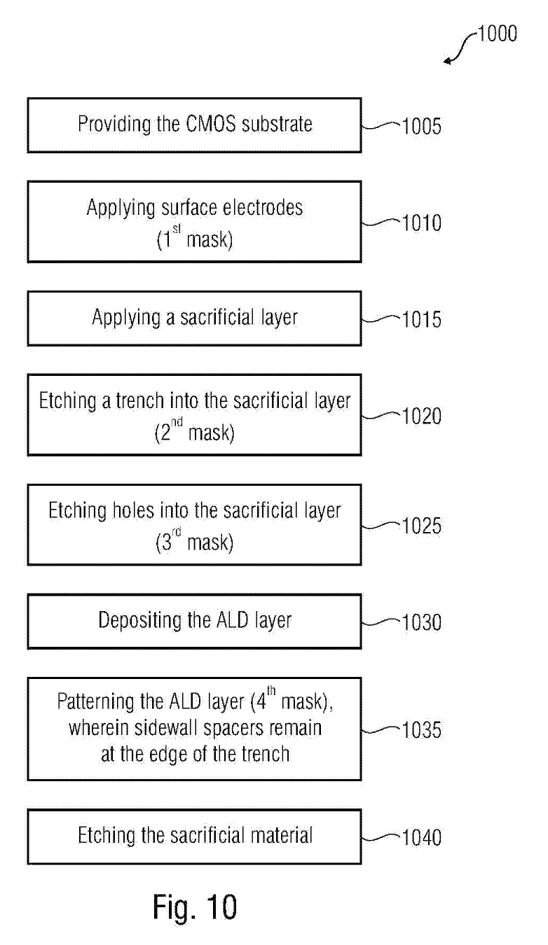

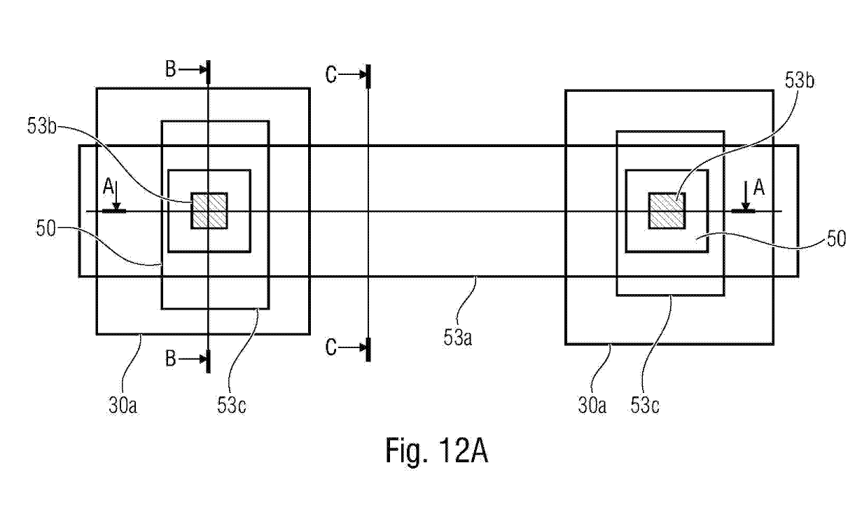

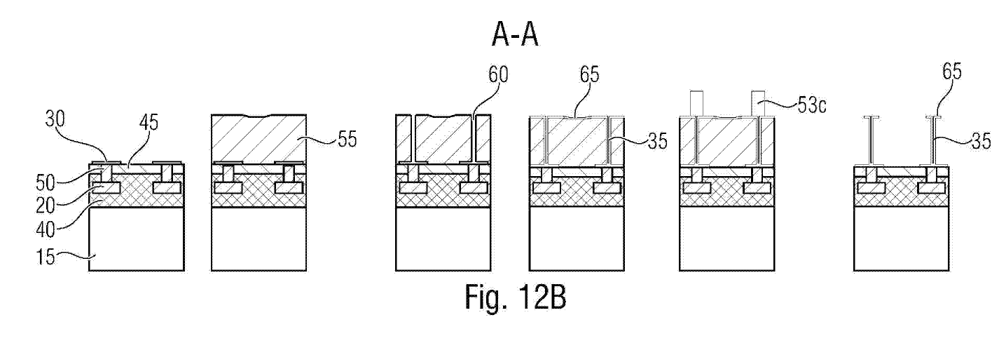

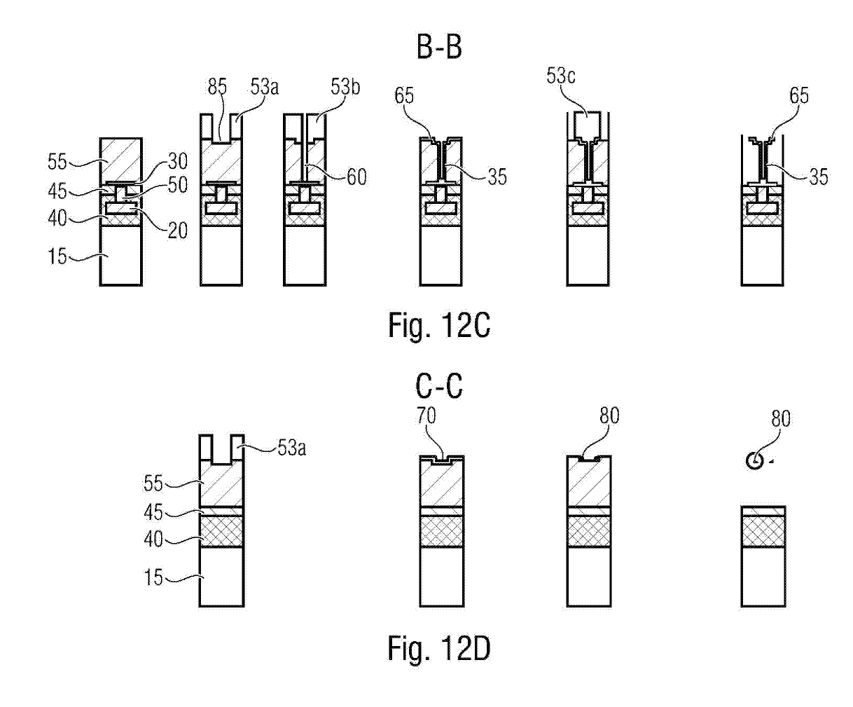

FIG. 10 shows a flow chart of a process 1000 for producing self-supporting nanowires using spacer technology. The reference numerals of the device features and masks used refer to the reference numerals of FIGS. 12a-d. After providing the CMOS substrate (step 1005) and applying the surface electrodes 30 (step 1010) using a first mask 30a, the sacrificial layer can be applied (step 1015). Using a second mask 53a, at first a trench can be introduced into the sacrificial layer (step 1020) and subsequently, the holes for the spacers be etched (step 1025) (mask 53b). The holes here are of a rectangular shape, but may also be of a round shape. It is also possible to exchange the two photo techniques, i.e. steps 1020 and 1025. Instead of etching the trench into the sacrificial material, it is alternatively also possible to define the trench by an additional layer (for example an oxide) and pattern the same selectively relative to the sacrificial material. This additional sacrificial material may be removed in the case of an oxide using HF vapor, for example. An ALD layer is deposited in a next step 1030 over the trenches and holes and patterned using a third mask 53c in the following step 1035. This allows parts of the surface to be etched selectively so that the ALD material forms the nanowires at the sidewalls of the trench. In addition, the third mask may be selected such that a plateau or suspension for the nanowires remains at the spacer, not being removed. Finally, the sacrificial material is removed.

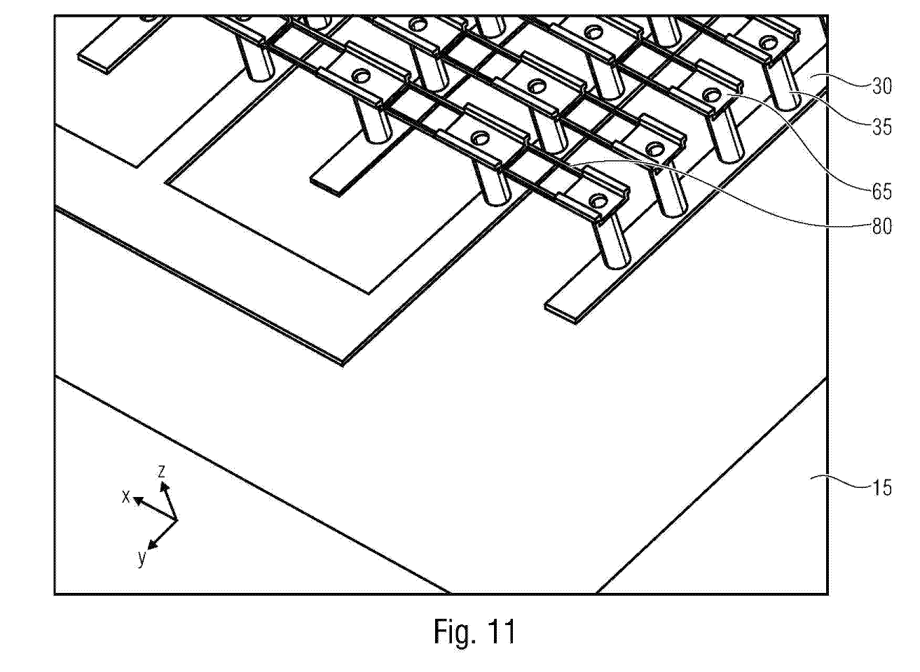

FIG. 11 shows an embodiment belonging to the process 1000 described in FIG. 10, in which nanowires 80 are spanned between two spacers 35.

Additionally, FIG. 12c-d show process cross-sections, and 12b a process longitudinal section in a schematic layout. The cross-sections and the longitudinal section are indicated in the overview drawing in FIG. 12a. The outlines of the masks used subsequently in FIGS. 12b-d can be seen in top view in FIG. 12a. Referring to FIG. 10, FIG. 12b shows a process longitudinal section of the device after steps 1010, 1015, 1025, 1030, 1035, and 1040. Additionally, FIG. 12c shows a process cross-section of the device after steps 1015, 1020, 1025, 1030, 1035, and 1040. Additionally, FIG. 12d shows a process cross-section of the device after steps 1020, 1030, 1035, and 1040. Step 1035 in FIG. 12d may be performed without using a mask in the region of the nanowires, since these will remain automatically with an anisotropic etching step. Only the region around the spacers, illustrated in FIGS. 12b, c, may be masked in order to allow a mechanical connection to the nanowires and not to damage the spacers.

The sensitivity of the structure is increased additionally by forming nanowires and the increase in the surface-to-volume ratios connected thereto. Here, the spacer technology may be combined with producing self-supporting bridges, as has been described before.

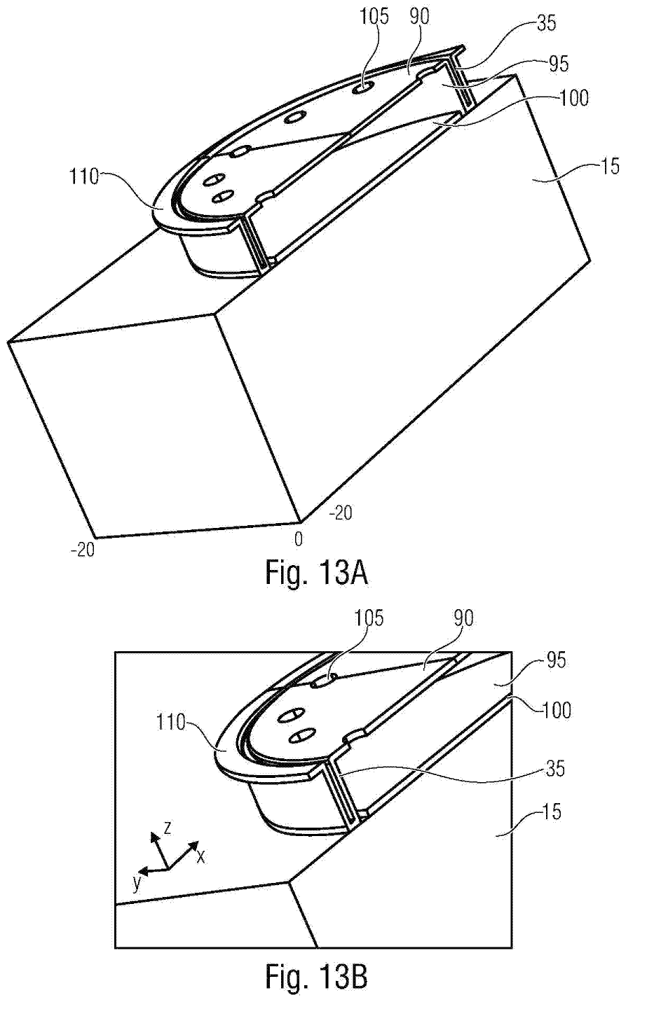

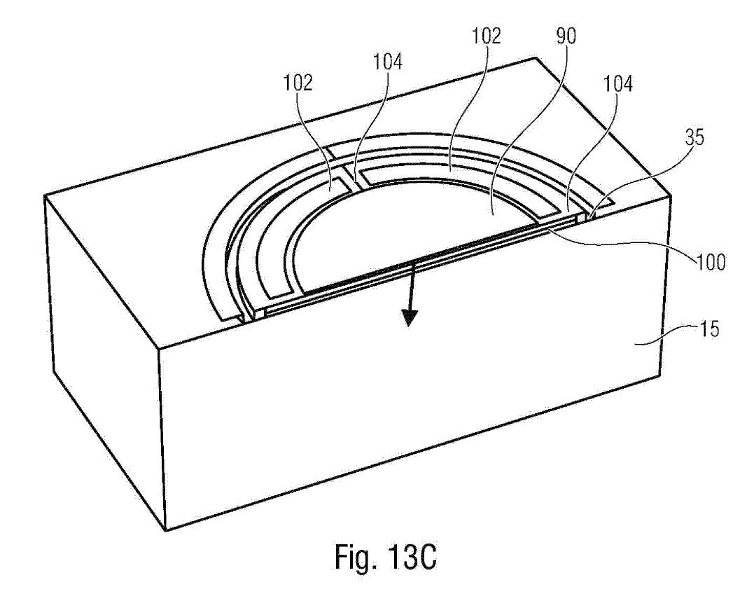

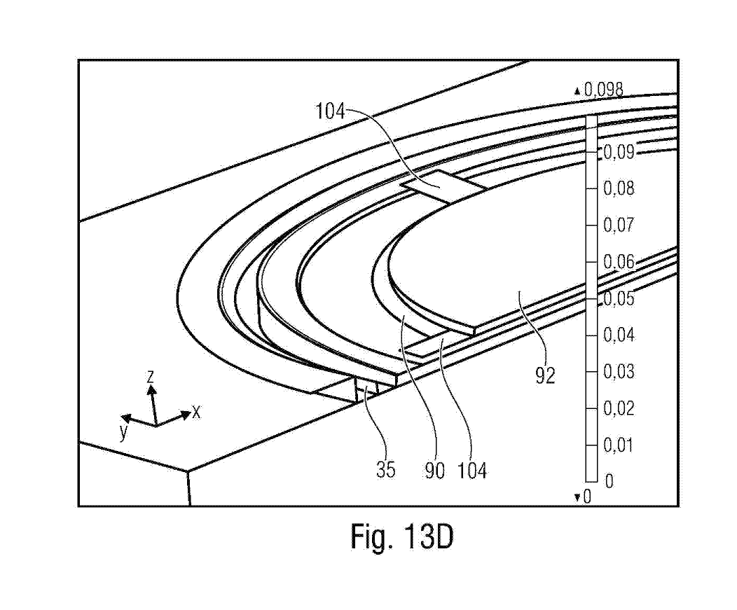

FIGS. 13a, b show another application of the inventive technology which relates to producing self-supporting membranes 90. These structures may be produced by the process flow in accordance with FIGS. 5a-f, or the process 400. An embodiment is illustrated in FIGS. 13a, b. In this case, a complete ring may be etched into the sacrificial layer, for example the amorphous silicon, as a spacer 35. The ring encloses a sensor area 95 formed by a cavity. A first electrode 100 is arranged within the cavity. Access holes 105 for exposing the cavity by etching are arranged within the sensor area. The second electrode 110 is also patterned, using the same or a different photo technique. The result is an electrical capacity which may be actuated electrostatically by applying a voltage between the electrodes. The structure may, for example, be used as a microphone or a (ultra-) sound transducer (resonator structure). A different application of the resonant structure relates to mass sensor systems. The change in resonant frequency here is measured by applying an additional mass. If the surface of the vibrating membrane is specifically functionalized in a chemical or biochemical manner, analytes may be identified specifically. The resonant frequency of the membrane may be adjusted by the diameter of the structure. Many other layout variations are possible. Different embodiments relate to capacitively excited bending wave sensors, for example. Finger electrodes, which generate bending waves in the membrane are arranged below the self-supporting membrane. In other words, the self-supporting element 35 can form a lid 120 of a cavity enclosed together with the spacer 35 and the substrate 15. An enlargement of the section is shown in FIG. 13b.

FIG. 13c shows another embodiment of a self-supporting membrane 90 which may be used as a tunable optical element on a CMOS substrate 15 and forms an FPI (Fabry Perot Interferometer), for example. The FPI may include two basically plane-parallel partly mirrored plates (for example partly transmissive mirrors) (reflection 90%, for example), the distance between which may be varied (in this case typically sub-micrometer to micrometer range). A mirror may be realized by the supported basic electrode 100, the second movable mirror by the membrane-like nanostructure 90. By applying a voltage between the two mirrors 90 and 100, the top mirror 90 may be moved by the electrostatic pressure in the direction of the arrow, i.e. in the direction of the fixed basic electrode 100 or membrane normal direction, which is how a wavelength which the FPI is sensitive to may be adjusted. The movable mirror may be realized using ALD technology, a transparent conductive material (for example transparent conductive oxide TOO), like AZO (aluminum-doped zinc oxide) or ITO (indium tin oxide), is used, which may be mirrored partly using one or several further layers (for example partly transmissive metal layer or stack of di-electric layers). The partly mirrored fixed basic electrode 100 may also be realized. A photo-sensitive diode may be arranged in the CMOS substrate below the partly mirrored basic electrode 100. The FPI may, thus, basically be formed to be integral, i.e. the movable mirror and the spacer are basically formed from one layer and produced (exclusively) by the methods of micro and nanotechnology, for example. This reduces the number of production steps compared to conventional Fabry-Perot elements, since applying an intermediate layer for the spacer between the semi-transmissive mirror for adjusting the sensitive wavelength of the FPI, for example, can be avoided, or is not necessary at all. In other words, the device 10 may form an optically tunable Fabry-Perot element comprising a movable mirror element containing an ALD layer, which may be actuated electrostatically.

The spacer 35, of an exemplarily round shape, which the membrane 90 is suspended to, for example, may comprise holes at four positions 102 so that the membrane 90 is suspended to the spacer at four lands 104, for example. The lands 104 may, for example, be movable. Thus, the membrane 90 suspended to the spacer 35, i.e. the movable mirror, may also be movable. In addition, the lands 104 may be configured to apply a restoring force to the membrane 90 so that the membrane 90 is held in its basic state or starting state with no external pressure acting on it.

FIG. 13d shows a section of FIG. 13c with a deflected membrane 90. The intensity of the deflection is described by the scale. The lands 104 may exhibit a gradually decreasing deflection, for example a large or maximum deflection at the transition to the membrane 90 and a minimum or no deflection at the transition to the spacers 35. Advantageously, the mirror area of the movable mirror remains basically planar, whereas the thin lands bend. A layer 92 may be applied onto the movable element, which is, for example, formed as a layer stack for a dielectric mirror and at the same time has a stiffening effect so that the mirror remains essentially planar.

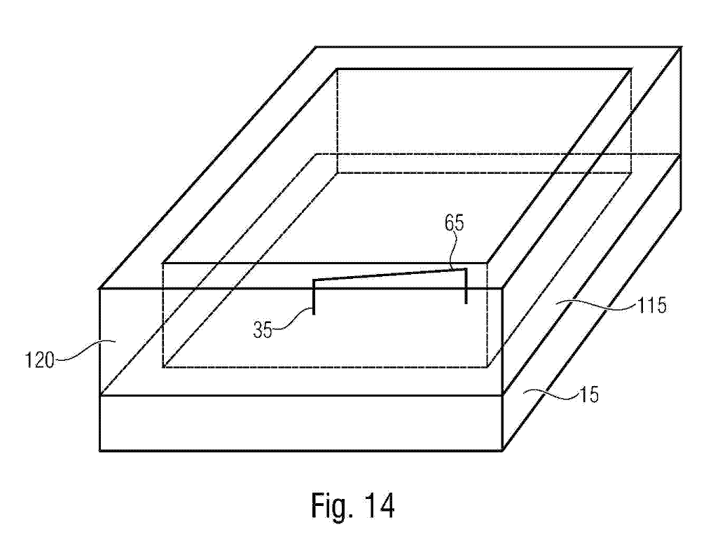

FIG. 14 shows a way of hermetically sealing the device from the outside. Thus, the structures are packed or enclosed in a chip scale package (housing in the order of magnitude of the die). Here, a solder frame 115 circularly enclosing the structure is applied onto the wafer substrate, which may be soldered hermetically with an associated solder frame 120 arranged on a lid (for example silicon or glass), for example in a so-called SLID process. The actual device is protected from environmental influences by the hermetic sealing and may, for example, be used as a finished element for soldering onto a board, for example. In other words, the device 10 may be arranged within a housing. A lid of the housing may, for example, comprise silicon or glass and an SLID solder frame may form a housing body.

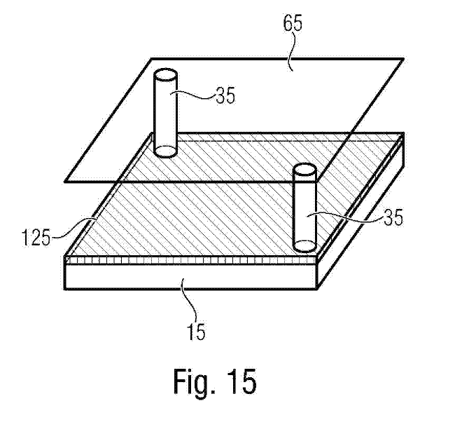

FIG. 15 shows another embodiment, for example that of a bolometer, similar to the embodiment of FIG. 1 or FIG. 6a. For stabilizing the spacer, an oxide layer 125 which is highly selective for the sacrificial material when finally etching is applied onto the wafer substrate before the sacrificial layer. If the sacrificial layer is removed, the oxide layer will remain and stabilize the spacers additionally. In contrast to the illustration in FIG. 15, the spacers may, as has already been described before, not only be implemented to be round, like a pin or hollow tube, but take any shape. In addition, using (thin) nanotubes in bolometers as may be obtained by the process described, for example by depositing an ALD layer at the walls of an opening of a sacrificial layer etched by means of DRIE, is of advantage. In particular with a continuous radiation measurement by means of a bolometer, it is of advantage to reduce heating of the bolometer by the radiation impinging thereon as far as possible. Due to the thin (ALD) layers, which may comprise layer thicknesses in the range of a few atomic layers, for example in the range from 1 nm to 20 nm, the nanotubes, but also the sensor structures comprise small a heat capacity or small a thermal mass. Thus, such bolometers may be cooled more effectively than bolometers of higher a heat capacity and, thus, allow more precise measurements over a longer period of time.

As has been described before, a (further) oxide layer which is also patterned by patterning the sacrificial layer, but is not removed by removing the sacrificial layer may be applied onto the main side 25 of the substrate 15. This is of advantage in that the micro or nanostructures are reinforced, for example at the basis of a micro or nanostructure, i.e. at that point where the micro or nanostructure, for example a nanotube, is based on the electrode. In this way, micro or nanostructures are able to better withstand shear forces or forces which do not act on the micro or nanostructures in the thickness direction, without bending or displacing, for example. The oxide layer may, thus, represent a reinforcement, support or stiffening of the micro or nanostructure. Subsequently, a method will be described using which the oxide layer may be patterned so that it is able to support the micro or nanostructures. Advantageously, the DRIE process for structuring the sacrificial layer may be a Bosch process, which—as has already been mentioned—comprises an alternating sequence of SF₆ and C₄F₈ steps. By switching the DRIE process to a pure C₄F₈ etching process when reaching the oxide layer, same may be patterned in the same etching equipment.

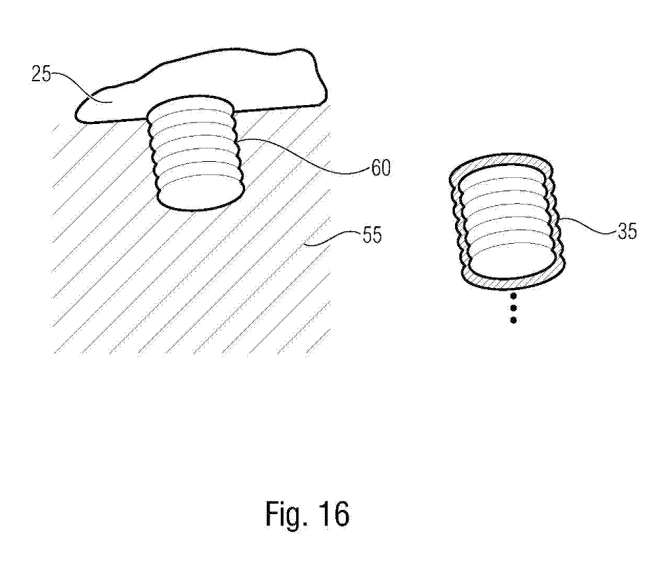

FIG. 16, on the left side, shows a basic illustration of a cross-section of a hole in a sacrificial layer 55 etched using a Bosch process, wherein the details also apply to DRIE in general. Waviness of the side walls which may result by the cyclic process of etching, passivating and removing the passivation on the floor of the hole etched up to there in a sputtering step is characteristic of the Bosch process. Thus, FIG. 16 shows an intermediate state of a hole not yet etched through the entire sacrificial layer. The manifestation, like the standard deviation of the lateral profile, of the waves of the walls may be influenced by a suitable selection of the process parameters, but never be avoided completely. In combination with the ALD method, the result is a typical appearance of the spacers and other parts of the micro or nanostructure, like the self-supporting nanowires, which is characterized by very steep, but not smooth, and very thin side walls as a negative of the hole in the sacrificial layer. What has been shown in FIG. 16 on the left side for a hole, of course also applies to the side walls (illustrated in FIG. 16 on the right side) of other parts, like the parts of the micro or nanostructures described before: they also exhibit waviness. This waviness means a further increase in the surface area of the structure, which is of advantage for many sensor applications.

Using the method illustrated in the present invention, and the general implementation of the device, specific examples of application can be produced. Only some examples of implementing the device will be described below.

A first application may be a multi-electrode array (MEA) for stimulating nerves and/or measuring biological signals. Multi-electrode arrays are devices, like interfaces in implants, which contain several needles, like nanotubes, using which neuronal signal can be received or emitted. Consequently, they serve as neuronal interfaces able to connect nerve cells to electronic circuits. Tubes or bar-like electrons which, on the one hand, allow highly specific stimulation of the nerves, may serve as electrodes or needles, for example when being operated at a current source, for example. On the other hand, nerves may also serve as a current source so that the multi-electrode array allows measuring nerve signals or biological signals in general. Due to the nanoscale, that is the small distance between the individual spacers, nanotubes, needles or electrodes to one another, in this case electrodes, for example sensor electrodes or sensor elements, a very high resolution can be achieved for measuring the biological signals. A particular advantage of the multi-electrode arrays shown, and generally of all further embodiments, is the direct arrangement of the spacers or nanoneedles or nanotubes on the CMOS substrate so that (small) measuring signals can be amplified largely with no interfering impedances (by a circuit integrated in the CMOS substrate), since long signal transmission paths, for example by lines to an external amplifier, are avoided.

Additionally, the method is highly suitable for forming gas sensors. A self-supporting bridge or a nanowire, for example made of a metal oxide, like ZnO, SnO₂, In₂O₃ or TiO₂, for example, may be formed as the sensitive part of the gas sensor, by means of an ALD or MOCVD layer, for example. It may be necessitated to optimize the material characteristics of the ALD layer by tempering treatments. Suspending the sensitive layers to the spacers allows effectively realizing the heating necessitated frequently in gas sensors. The sensor area, for example, may be heated to a temperature of 200° to 300° Celsius usual for gas sensors by providing same with a comparatively small current (due to the nanoscale of the structures). This is made possible by the small thermal mass, for example. When the spacers are additionally formed from a basically thermally insulating material, the gas sensor has no thermal mass at all, or only a small thermal mass. In other words, the spacers may additionally be manufactured from a basically thermally insulating material, thereby further reducing the thermal mass of the gas sensor or the spacers and achieving thermal decoupling of the sensor area from the substrate by means of the spacers.

Another embodiment may be a bio sensor. A biologically active layer or functionalizing layer for detecting biological substances (bio-functionalizing layer), a so-called biological catching layer (in accordance with the lock-and-key principle, for example antibodies-antigens), may be applied onto a self-supporting element. The biological catching layer reacts to environmental influences by changing its physical characteristics, in particular the electrical resistance, which may be converted by the basic material of the self-supporting element to form an electrical signal.

In addition, it is possible to form capacitive humidity sensors, which exemplarily use a U profile as the sensor area. Thus, two U profiles arranged next to each other form two electrodes between which a dielectric is arranged which changes its dielectric constant when receiving or emitting humidity, that is comprises a humidity-sensitive material, for example. Thus, a capacitor is formed the electrical field of which is influenced by the changing dielectric constant. When calibrating the sensor in a suitable manner, this allows measuring the absolute humidity. Furthermore, it is also possible to arrange three or more U profiles next to one another and to fill the intermediate spaces between the U profiles with the same dielectric. This allows implementing a relative humidity sensor which is able to measure a humidity gradient, for example.

A nanofuse in accordance with a fuse link principle may also be produced from a self-supporting nanowire, for example. As long as the power is limited, the nanowire behaves like an electrical conductor. However, when too high a current is applied over too long a period, the nanowire heats up to an extent such that it is blown and there is no current flow anymore.

In other words, the present invention describes CMOS-integratable 3D nano or microstructures and methods for producing same in embodiments. The object of the invention is producing 3D micro and nanostructures (referred to as “nanostructures” below) which may be realized using semiconductor production methods and may be “placed” directly on a CMOS substrate (optionally already comprising an integrated circuit). The nanostructures are formed as a three-dimensional structure from a thin layer or a thin layer stack, using a sacrificial technique. The typical dimensions perpendicular to the thickness of the nanostructures produced are smaller than 1 μm, typically in a range from 200-400 nm, but may also be several 100 μm (see the embodiments), wherein the thickness (of side walls) of the nanostructures produced may be in a range of several atomic layers, for example in a range from 1 nm to 50 nm, for example smaller than or equaling 5 nm, 10 nm or 50 nm. The nanostructures produced using the inventive manufacturing process may be used in particular for realizing 3D electrodes, for example in so-called multi-electrode arrays for measuring or for stimulating nerve cells in implants. However, by using another lithography mask apart from the electrode structures, the inventive technology allows realizing further sensors and actuator structures:

Examples of possible structures are:
3D nanotubes as electrode arrays, in particular as so-called multi-electrode arrays in medical technology or bio sensor systems for contacting biological materials (particularly cells). Nerves may be stimulated or signals be derived by this.
Self-supporting 3D nanobridges, for example as sensing resistance bridges in gas sensor systems, as sensing resistance bridges in bio sensor systems, as optical sensor elements or as so-called micro or nanofuses (“fuses”). The self-supporting bridges may particularly also be connected electrically individually so that imaging arrays may be formed.
Self-supporting membranes which may be used as sound transducers (as sensors or actuators) or as mass sensors, for example. These membranes may be excited to vibrate mechanically by an electrode in an electrostatic manner.
Capacitive 3D structures which are formed, for example, in connection with a humidity-sensitive material, for example a polyimide as a humidity meter, or as capacitive sensors for impedance-spectrometrical measurements in bio sensor systems.

Using ALD layers for sensors and electromechanical 3D structures has several advantages: a very large surface area may be generated by the 3D arrangement. This is of advantage for sensor systems which are based on surface reactions (for example gas, chemo or bio sensors). Since the ALD structures may specifically be deposited to be very thin (nanoscale), a large surface-to-volume ratio is achieved. The term “ALD layer” here is used in the sense of a “super-conformally” depositing layer. This is, for example, also true for so-called MOCVD (metal organic chemical vapor deposition) layers.

In summary, what is disclosed is an easy process for producing self-supporting 3D nano and microstructures which is CMOS-compatible and may be realized in a cheap and monolithic manner using conventional apparatuses of semiconductor technology. The process may thus be places onto a prepared CMOS substrate in a “post-CMOS” module manner so that a plurality of intelligent sensors may be realized.

The terms CMOS substrate, wafer substrate and substrate are not considered to be limiting relative to the respective other terms and additionally refer to a basis onto which the micro or nanostructures may be formed. This may, for example, be a silicon wafer or a chip diced already.

Embodiments show a method for producing a device 10 comprising a step of providing a substrate 15 comprising an electrode 30 which is exposed at a main side 25 of the substrate, and forming a micro or nanostructure which comprises a spacer 35 which is based on the electrode 30. The fact that the spacer 35 is based on the electrode exemplarily means that the electrode and the spacer are connected to each other electrically and/or mechanically. Forming the micro or nanostructure may comprise the following steps: depositing a sacrificial layer 55 on the main side, wherein the sacrificial layer 55 comprises amorphous silicon (a-Si) or silicon dioxide (SiO2), patterning a hole and/or trench 60 in the sacrificial layer by means of a DRIE process, coating the sacrificial layer by means of ALD or MOCVD so that the material of the nano or microstructure forms at the hole and/or trench, and removing the sacrificial layer 55 in order to obtain the device 10.

In accordance with further embodiments, a device 10 is shown which comprises a substrate 15 and a micro or nanostructure. The substrate may comprise an electrode 30 which is exposed at a main side 25 of the substrate 15. The micro or nanostructure may comprise a spacer 35 which is based on the electrode 30, wherein the micro or nanostructure is produced by means of ALD or MOCVD coating of a sacrificial layer 55 patterned by a DRIE process, on the main side of the substrate and subsequently removing the sacrificial layer, wherein the sacrificial layer 55 contains amorphous silicon (a-Si) or silicon dioxide (SiO2).

Although some aspects have been described in connection with a device, it is to be understood that these aspects also represent a description of the corresponding method meaning that a block or element of a device is to be understood to be also a corresponding method step or feature of a method step. In analogy, aspects having been described in connection with or as a method step also represent a description of a corresponding block or detail or feature of a corresponding device.

While this invention has been described in terms of several embodiments, there are alterations, permutations, and equivalents which will be apparent to others skilled in the art and which fall within the scope of this invention. It should also be noted that there are many alternative ways of implementing the methods and compositions of the present invention. It is therefore intended that the following appended claims be interpreted as including all such alterations, permutations, and equivalents as fall within the true spirit and scope of the present invention.

1. A method for producing a device, comprising:
providing a substrate comprising an electrode which is exposed at a main side of the substrate, and
forming a micro or nanostructure which comprises a spacer which is based on the electrode, wherein forming comprises:
depositing a sacrificial layer on the main side, wherein the sacrificial layer comprises amorphous silicon;
patterning a hole and/or trench into the sacrificial layer by means of a DRIE process;
coating the sacrificial layer by means of ALD so that material of the nano or microstructure forms at the hole and/or trench;
removing the sacrificial layer.

2. The method for producing a device in accordance with claim 1, wherein the substrate comprises integrated members.

3. The method in accordance with claim 1, wherein the method, before depositing the sacrificial layer, comprises:
applying an oxide layer on the main side of the substrate which is also patterned by patterning the sacrificial layer, but not removed by removing the sacrificial layer, thereby additionally stabilizing the spacer.

4. The method in accordance with claim 1, wherein coating comprises coating with a coating material over the entire area, and the method, after coating the sacrificial layer, comprises:
removing the coating material on a side of the sacrificial layer facing away from the substrate so that the material of the micro or nanostructure remains in the hole or trench.

5. The method in accordance with claim 4, wherein the coating material on the sacrificial layer is patterned and not removed completely in order to form a self-supporting element of the micro or nanostructure.

6. The method in accordance with claim 5, wherein the self-supporting element comprises a nanowire.

7. The method in accordance with claim 1, wherein the sacrificial layer comprises a-Si and is removed by means of isotropic etching using SF₆ or XeF₂, or wherein the sacrificial layer is made of SiO₂ and is removed using HF vapor.

8. The method in accordance with claim 1, wherein the DRIE process is a Bosch process.

9. The method in accordance with claim 1, wherein the method comprises a recurring sequence of:
depositing a sacrificial layer on the main side;
patterning a hole and/or trench into the sacrificial layer by means of a DRIE process;
coating the sacrificial layer by means of ALD or MOCVD so that material of the nano or microstructure forms at the walls of the hole and/or trench.

10. The method in accordance with claim 9, wherein the sacrificial layers of the recurring sequence are removed together.

11. The method in accordance with claim 1, wherein the DRIE process comprises a cyclic process of etching, passivating and removing the passivation on the floor of a hole etched up to there, resulting in a waviness of the side walls of the hole and/or trench in the sacrificial layer.

12. The method in accordance with claim 1, wherein the DRIE process is a Bosch process and comprises a cyclic process of etching using SF₆ or C₄F₈, passivating and removing the passivation on the floor of a hole etched up to there, resulting in a waviness of the side walls of the hole and/or trench in the sacrificial layer.

13. The method in accordance with claim 1, comprising:
applying a solder frame on the substrate, wherein the solder frame surrounds the micro or nanostructure;
arranging a lid on the solder frame;
soldering the lid with the solder frame on the wafer substrate in order to achieve a chip-scale package, wherein the chip-scale package packages the micro or nanostructures.

14. The method in accordance with claim 13, wherein soldering is executed by means of SLID.

15. A device
comprising a substrate which comprises an electrode which is exposed at a main side of the substrate,
a micro or nanostructure which comprises a spacer which is based on the electrode, wherein the micro or nanostructure is produced by means of ALD coating a sacrificial layer patterned by the DRIE process, on the main side of the substrate and subsequently removing the sacrificial layer, wherein the sacrificial layer comprises amorphous silicon.

16. The device in accordance with claim 15, wherein the spacer is hollow.

17. The device in accordance with claim 15, wherein the spacer is implemented to be solid.

18. The device in accordance with claim 15, wherein the micro or nanostructure additionally comprises a self-supporting element which is suspended at the spacer to be self-supporting.

19. The device in accordance with claim 15, wherein the spacer comprises an aspect ratio of a height relative to a width of the spacer of greater than or equaling 1.

20. The device in accordance with claim 18, wherein the self-supporting element is implemented to be a bridge between the spacer and another spacer which is based on another electrode formed on the substrate.

21. The device in accordance with claim 18, wherein the self-supporting element is formed from mutually overlapping layers of different materials.

22. The device in accordance with claim 21, wherein the mutually overlapping layers of different materials comprise different physical characteristics which form an interface for forming a sensor.

23. The device in accordance with claim 18, wherein a layer of the self-supporting element is made of a humidity-sensitive material.

24. The device in accordance with claim 18, wherein a layer of the self-supporting element comprises a functionalizing layer for detecting biological substances.

25. The device in accordance with claim 18, wherein a layer of the self-supporting element comprises ruthenium, ZnO, SnO₂ or TiO₂.

26. The device in accordance with claim 18, wherein a further spacer to which a further self-supporting element is suspended in a self-supporting manner is arranged on the self-supporting element.

27. The device in accordance with claim 18, wherein the self-supporting element forms a lid of a cavity enclosed in connection with the spacer and the substrate.

28. The device in accordance with claim 15, wherein the micro or nanostructure is electrically conductive.

29. The device in accordance with claim 15, wherein the device forms a sensor for detecting light, heat radiation or a chemical or biological composition in an environment adjacent to the main side.

30. The device in accordance with claim 15, wherein the spacer is formed from layers of different materials

31. The device in accordance with claim 30, wherein a layer of the spacer comprises a metal.

32. The device in accordance with claim 30, wherein a layer thickness is smaller than or equaling 100 nm.

33. The device in accordance with claim 15, wherein a height of the spacer is smaller than or equaling 10 μm.

34. The device in accordance with claim 15, wherein the spacer is arranged regularly in the shape of a matrix together with further spacers which are arranged on the main side and based on further electrodes.

35. The device in accordance with claim 34, wherein the device forms an imaging element.

36. The device in accordance with claim 34, wherein the spacers are formed as parallel U profiles or as hollow nanotubes projecting from the main side in a two-dimensional array.

37. The device in accordance with claim 15, wherein a plurality of spacers are arranged on an electrode.

38. The device in accordance with claim 15, wherein the device is arranged in a housing.

39. The device in accordance with claim 38, wherein a lid of the housing is formed from silicon or glass and an SLID solder frame forms a body of the housing.

40. The device in accordance with claim 15, wherein the device forms a multi-electrode array for stimulating nerves and/or for measuring biological signals from tubular or rod-shaped electrodes.

41. The device in accordance with claim 15, wherein the device forms a gas sensor implemented as a self-supporting bridge made of a gas-sensitive metal oxide.

42. The device in accordance with claim 41, wherein the spacers are metallic and the functional layer is a metal oxide.

43. The device in accordance with claim 15, wherein the device is implemented as a bio sensor, wherein the nanowire structure is provided with a biological catching layer.

44. The device in accordance with claim 15, wherein the device forms a capacitive humidity sensor made of U profile-shaped spacers and a humidity-sensitive material which changes a dielectric constant when receiving humidity introduced into the intermediate spaces of the electrodes.

45. The device in accordance with claim 15, wherein the device forms a self-supporting metallic nanowire structure as a nanofuse which is destroyed by electrical load.

46. The device in accordance with claim 15, wherein the device forms a self-supporting metallic nanowire structure as a programmable memory element (nano ROM).

47. The device in accordance with claim 15, wherein the device forms a bio sensor comprising a self-supporting nanowire and a layer acting as bio functionalization.

48. The device in accordance with claim 15, wherein the device forms a resonant sensor as a self-supporting membrane structure with an underlying fixed supported electrode for electrostatic actuation.

49. The device in accordance with claim 15, wherein the device forms an optically tunable Fabry-Perot element comprising a movable mirror element comprising an ALD layer which may be actuated electrostatically.

50. The device in accordance with claim 15, wherein the device forms a bolometer.

51. The device in accordance with claim 15, wherein a layer thickness of the micro or nanostructure is smaller than 50 nm, smaller than 10 nm or smaller than 5 nm.

52. The device in accordance with claim 15, wherein the micro or nanostructure comprises a side wall exhibiting a waviness, wherein the waviness results from coating side walls of a hole and/or trench etched into the sacrificial layer by means of a DRIE process.
